(19) United States
(12) Patent Application Publication
(10) Pub. No.: US 2026/0362852 A1
(43) Pub. Date: Nov. 12, 2026

(54) METHOD FOR MANUFACTURING ULTRA-THIN TYPE SEMICONDUCTOR DIE

(71) Applicant: WAVELORD CO., LTD, Hwaseong-si (KR)

(72) Inventors: Juneo SONG, Suwon-si (KR); Young Hun HAN, Osan-si (KR); Hyeong Seon YUN, Paju-si (KR); Ji Hyung MOON, Gunpo-si (KR)

(73) Assignee: WAVELORD CO., LTD, Hwaseong-si (KR)

(21) Appl. No.: 19/134,759

(22) PCT Filed: Nov. 27, 2023
(86) PCT No.: PCT/KR2023/019248

§ 371 Date: Jun. 2, 2025

(30) Foreign Application Priority Data
Dec. 2, 2022 (KR) 10-2022-0166721
Dec. 2, 2022 (KR) 10-2022-0166728
Jul. 11, 2023 (KR) 10-2023-0090001

(51) Int. Cl. H10H 20/01

(52) U.S. Cl. CPC H10H 20/018; H10H 20/019; H10H 20/021

(57) ABSTRACT

The present invention relates to a method for manufacturing an ultra-thin type semiconductor die in which a sapphire substrate of a semiconductor die is molded in an ultra-thin type by bonding, to a second substrate, a semiconductor layer formed on the top surface of a first substrate, and then molding the first substrate in an ultra-thin type, thereby manufacturing a smaller semiconductor light emitting device or power semiconductor device.

### TECHNICAL FIELD

The present invention relates to a method of manufacturing an ultra-thin type semiconductor die, and more specifically, to a method of manufacturing an ultra-thin type semiconductor die in which a sapphire substrate of a semiconductor die is shaped into an ultra-thin type so as to manufacture a small semiconductor device.

### BACKGROUND ART

First, from the perspective of semiconductor light-emitting devices, as smaller dies (epitaxial dies or chip dies) are required for manufacturing mini or micro level semiconductor light-emitting devices, a process technology for shaping a thinner sapphire is required.

That is, in order to achieve size reduction of an epitaxy die or a chip die in terms of an aspect ratio, it is basically essential to reduce a thickness of a sapphire that is a final growth substrate (or support substrate). However, a thickness of a sapphire that is a current growth substrate (or support substrate) is limited to the range of 80 μm to 70 μm, and when the thickness is reduced to less than 50 μm, the issue of sapphire substrate breakage occurs due to residual stress that is present inside a wafer.

For this reason, there are attempts to grow a Group-III nitride semiconductor by shaping a thickness of a final sapphire growth substrate to be thin from the beginning, but there is a problem that the die or wafer is deformed and damaged during a shaping or transfer process due to thermo-mechanical induced stress generated by a difference in lattice constant (LC) and coefficient of thermal expansion (CTE) between the sapphire growth substrate and the Group-III nitride semiconductor.

In addition, in terms of a power semiconductor device, a GaN on sapphire method, which has good crystal quality next to a power semiconductor device manufactured by a GaN on GaN method for the advancement of crystal quality, is widely used, and the epitaxial film deposition technology in this method has already been developed and matured. However, the only drawback of the GaN on sapphire method is that sapphire has poor heat dissipation ability, which limits its application to high-output products.

In order to overcome the above drawback, high-output products have been developed using SiC and Si growth substrates with high heat dissipation, but the high-output products are inferior to epitaxy grown on sapphire growth substrates in terms of performance, crystal quality, defects, and production costs.

Furthermore, in order to improve the heat dissipation performance of the power semiconductor devices, when the growth substrate is completely removed and a high-heat dissipation support substrate is bonded, there is an advantage that the heat dissipation performance of the power semiconductor device can be significantly improved, but there is a problem that the long-term reliability of the power semiconductor device is adversely affected due to a thermal-mechanical impact and residual compressive stress relief during the process of removing the growth substrate and bonding the high-heat dissipation support substrate.

### DETAILED DESCRIPTION OF INVENTION

### Technical Problem

In order to solve the above problems, the present invention is directed to providing a method of manufacturing an ultra-thin type semiconductor die in which a sapphire substrate of a semiconductor die is formed into an ultra-thin type so as to manufacture a smaller semiconductor device.

### Technical Solution

According to one aspect of the present invention, a method of manufacturing an ultra-thin type semiconductor die includes a preparation operation of preparing a first substrate on which a semiconductor layer is grown on a top surface thereof, a bonding operation of bonding a second substrate to the semiconductor layer through a bonding layer, a shaping operation of shaping the first substrate into an ultra-thin shape, a guide groove formation operation of forming a guide groove in a surface of or inside the first substrate, which is shaped into an ultra-thin shape, in a die unit, and a removal operation of removing the second substrate and the bonding layer.

In addition, in the removal operation, when the second substrate is removed, cracks may be generated from the guide groove of the first substrate, the cracks may propagate to the semiconductor layer, and the first substrate and the semiconductor layer may be separated into die units due to the propagating cracks.

In addition, the first substrate and the second substrate may be sapphire substrates.

In addition, the semiconductor layer may include a first semiconductor region having a first conductivity, a second semiconductor region having a second conductivity different from the first conductivity, and an active region which is interposed between the first semiconductor region and the second semiconductor region and generates light using recombination of electrons and holes.

In addition, after the preparation operation, the method may include an electrode formation operation of forming an electrode on the semiconductor layer, wherein the electrode may include at least one of a p-type ohmic electrode and an n-type ohmic electrode.

In addition, a passivation layer covering at least a portion of the electrode may be formed on the semiconductor layer.

In addition, in the bonding operation, a protective layer may be formed to cover the electrode, and the second substrate may be bonded to the protective layer through the bonding layer, and in the removal operation, the second substrate may be removed, and the bonding layer and the protective layer may be removed.

In addition, a thickness of the shaped first substrate may be less than 50 μm.

In addition, the removal operation may be an operation of removing the second substrate using a laser lift off (LLO) technique.

In addition, the second substrate may be provided with a sacrificial separation layer.

According to another aspect of the present invention, a method of manufacturing an ultra-thin type semiconductor die includes a preparation operation of preparing a first substrate on which a semiconductor layer is grown on a top surface thereof, a bonding operation of bonding a second substrate to the semiconductor layer through a bonding layer, a shaping operation of removing the first substrate to expose the semiconductor layer, bonding a third substrate to the exposed semiconductor layer through a bonding layer, and then shaping the third substrate into an ultra-thin shape, a guide groove formation operation of forming a guide groove in a surface of or inside the third substrate, which is shaped into an ultra-thin shape, in a die unit, and a removal operation of removing the second substrate and the bonding layer.

In addition, in the removal operation, when the second substrate is removed, cracks may be generated from the guide groove of the third substrate, the cracks may propagate to the semiconductor layer, and the third substrate and the semiconductor layer may be separated into die units due to the propagating cracks.

In addition, the first substrate, the second substrate, and the third substrate may be sapphire substrates.

In addition, the semiconductor layer may include a first semiconductor region having a first conductivity, a second semiconductor region having a second conductivity different from the first conductivity, and an active region which is interposed between the first semiconductor region and the second semiconductor region and generates light using recombination of electrons and holes.

In addition, after the preparation operation, the method may include an electrode formation operation of forming an electrode on the semiconductor layer, wherein the electrode may include at least one of a p-type ohmic electrode and an n-type ohmic electrode.

In addition, a passivation layer covering at least a portion of the electrode may be formed on the semiconductor layer.

In addition, in the bonding operation, a protective layer is formed to cover the electrode, and the second substrate is bonded to the protective layer through the bonding layer, and in the removal operation, the second substrate may be removed, and the bonding layer and the protective layer may be removed.

In addition, a thickness of the shaped first substrate may be less than 50 μm.

In addition, the removal operation may be an operation of removing the second substrate using a laser lift off (LLO) technique.

In addition, the second substrate may be provided with a sacrificial separation layer.

In addition, in the shaping operation, a lower electrode may be formed on the exposed semiconductor layer, the third substrate may be bonded to the lower electrode through the bonding layer, and then the third substrate may be shaped into an ultra-thin shape.

According to still another aspect of the present invention, a method of manufacturing an ultra-thin type semiconductor die includes a preparation operation of preparing a first substrate on which a semiconductor layer is grown on a top surface thereof, a bonding operation of etching and separating the semiconductor layer into die units, and then bonding a second substrate to the semiconductor layer through a bonding layer, a shaping operation of shaping the first substrate into an ultra-thin shape, a guide groove formation operation of forming a guide groove in a surface of or inside the first substrate, which is shaped into an ultra-thin shape, in a die unit, and a removal operation of removing the second substrate and the bonding layer.

In addition, in the removal operation, when the second substrate is removed, cracks may be generated from the guide groove of the first substrate, and the first substrate may be separated into a die unit due to the generated cracks.

In addition, the first substrate and the second substrate may be sapphire substrates.

In addition, the semiconductor layer may include a first semiconductor region having a first conductivity, a second semiconductor region having a second conductivity different from the first conductivity, and an active region which is interposed between the first semiconductor region and the second semiconductor region and generates light using recombination of electrons and holes.

In addition, after the preparation operation, the method may include an electrode formation operation of forming an electrode on the semiconductor layer, wherein the electrode may include at least one of a p-type ohmic electrode and an n-type ohmic electrode.

In addition, in the bonding operation, a protective layer may be formed to cover the electrode, and the second substrate may be bonded to the protective layer through the bonding layer, and in the removal operation, the second substrate may be removed, and the bonding layer and the protective layer may be removed.

In addition, a thickness of the shaped first substrate may be less than 50 μm.

In addition, the semiconductor layer may include a buffer layer, a channel layer which is disposed on the buffer layer and in which a two-dimensional electron gas (2 DEG) is formed, and a barrier layer disposed on the channel layer.

In addition, after the preparation operation, the method may include an electrode formation operation of forming an electrode on the semiconductor layer, and the electrode may include at least one of a source electrode, a drain electrode, and a gate electrode.

In addition, in the bonding operation, a protective layer may be formed to cover the electrode, and the second substrate may be bonded to the protective layer through the bonding layer, and in the removal operation, the second substrate may be removed, and the bonding layer and the protective layer may be removed.

In addition, a thickness of the shaped first substrate may be less than 100 μm.

In addition, a high-heat dissipation support substrate may be bonded to the shaped first substrate through the bonding layer.

In addition, a metal plated layer for heat dissipation may be formed on the shaped first substrate.

### Advantageous Effects

According to the present invention, there is an effect of being able to manufacture a smaller semiconductor light-emitting device through a semiconductor die (epitaxial die or chip die) having an ultra-thin thickness of less than 50 μm.

In addition, according to the present invention, a high-heat dissipation support substrate is bonded to an ultra-thin type sapphire substrate or a copper (Cu) electroplated layer for heat dissipation is formed, defects of power semiconductor devices can be significantly reduced, and there is an effect that enables the manufacture of high-performance power semiconductor devices.

Meanwhile, the effects of the present invention are not limited to the effects mentioned above, and various effects may be included within a range obvious to those skilled in the art from the content which will be described below.

### DESCRIPTION OF DRAWINGS

FIG. 1 is a flowchart illustrating a method of manufacturing an ultra-thin type semiconductor die according to a first embodiment of the present invention.

FIGS. 2 and 3 are diagrams illustrating a process of manufacturing an ultra-thin type semiconductor die by the method of manufacturing an ultra-thin type semiconductor die according to the first embodiment of the present invention.

FIGS. 4 and 5 are diagrams illustrating examples of ultra-thin type semiconductor dies manufactured by the method of manufacturing an ultra-thin type semiconductor die according to the first embodiment of the present invention.

FIG. 6 is a flowchart illustrating a method of manufacturing an ultra-thin type semiconductor die according to a second embodiment of the present invention.

FIGS. 7 and 8 are diagrams illustrating a process of manufacturing an ultra-thin type semiconductor die by the method of manufacturing an ultra-thin type semiconductor die according to the second embodiment of the present invention.

FIG. 9 is a flowchart illustrating a method of manufacturing an ultra-thin type semiconductor die according to a third embodiment of the present invention.

FIGS. 10 and 11 are diagrams illustrating a process of manufacturing an ultra-thin type semiconductor die by the method of manufacturing an ultra-thin type semiconductor die according to the third embodiment of the present invention.

FIG. 12 is a flowchart illustrating a method of manufacturing an ultra-thin type semiconductor die according to a fourth embodiment of the present invention.

FIGS. 13 and 14 are diagrams illustrating a process of manufacturing an ultra-thin type semiconductor die by the method of manufacturing an ultra-thin type semiconductor die according to the fourth embodiment of the present invention.

FIG. 15 is a flowchart illustrating a method of manufacturing an ultra-thin type semiconductor die according to a fifth embodiment of the present invention.

FIGS. 16 and 17 are diagrams illustrating a process of manufacturing an ultra-thin type semiconductor die by the method of manufacturing an ultra-thin type semiconductor die according to the fifth embodiment of the present invention.

### MODES OF THE INVENTION

Hereinafter, some embodiments of the present invention will be described in detail with reference to the illustrative drawings. In giving reference numerals to components of the drawings, the same reference numerals are given to the same components even though the same components are shown in different drawings.

In addition, in describing embodiments of the present invention, when a detailed description of related known configurations or functions is determined to hinder the understanding of the embodiments of the present invention, the detailed description thereof will be omitted.

Further, in describing components of the embodiment of the present disclosure, terms such as a first, a second, A, B, (a), (b), etc., can be used. These terms are intended to distinguish one component from other components, but the nature and the order or sequence of the components is not limited by those terms.

Hereinafter, with reference to the accompanying drawings, a method S100 of manufacturing an ultra-thin type semiconductor die according to a first embodiment of the present invention will be described in detail.

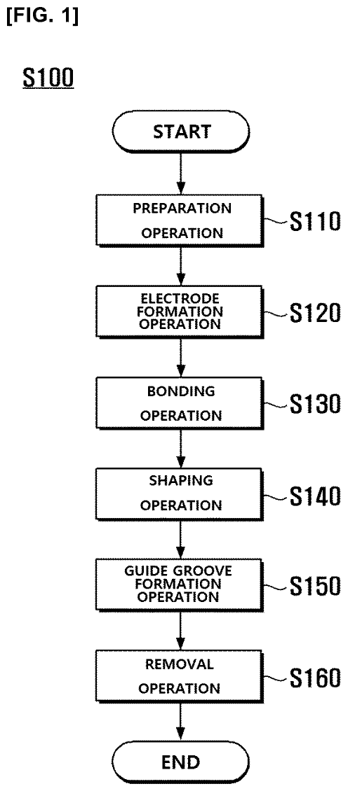

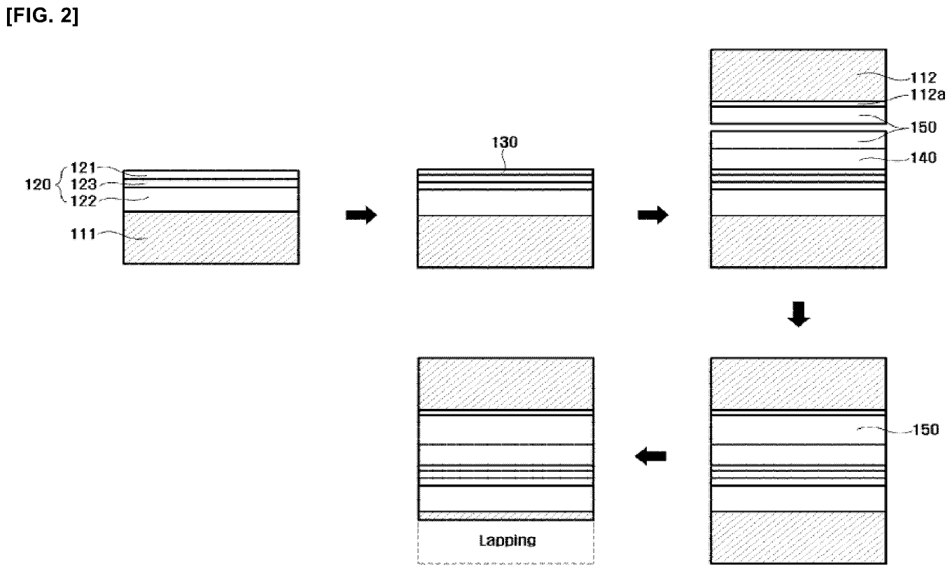

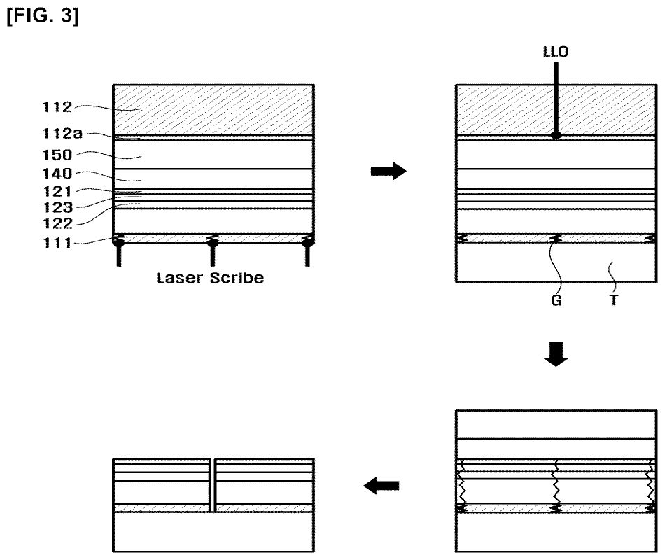

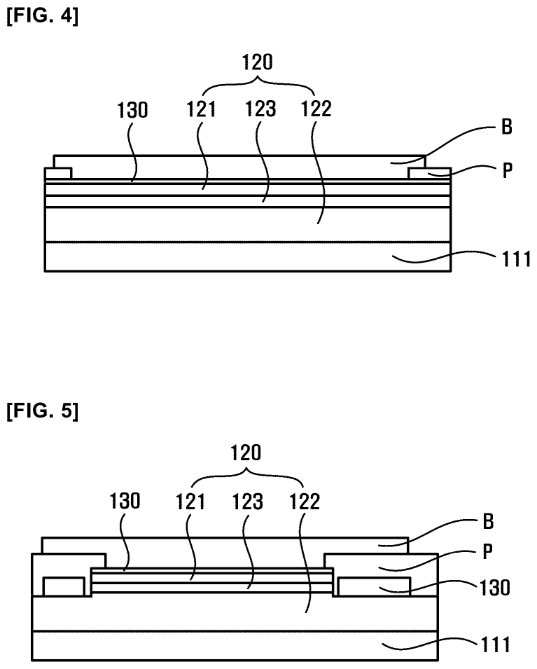

FIG. 1 is a flowchart illustrating the method S100 of manufacturing an ultra-thin type semiconductor die according to the first embodiment of the present invention, FIGS. 2 and 3 are diagrams illustrating a process of manufacturing an ultra-thin type semiconductor die by the method S100 of manufacturing an ultra-thin type semiconductor die according to the first embodiment of the present invention, and FIGS. 4 and 5 are diagrams illustrating examples of ultra-thin type semiconductor dies manufactured by the method S100 of manufacturing an ultra-thin type semiconductor die according to the first embodiment of the present invention.

As shown in FIGS. 1 to 3, the method S100 of manufacturing an ultra-thin type semiconductor die according to the first embodiment of the present invention is for manufacturing a small die (epitaxial die or chip die) having a thickness of less than 50 μm, which was previously impossible, and includes a preparation operation S110, an electrode formation operation S120, a bonding operation S130, a shaping operation S140, a guide groove formation operation S150, and a removal operation S160.

The preparation operation S110 is an operation of preparing a first substrate 111 and the second substrate 112 and is an operation of preparing the first substrate 111 on which the semiconductor layer 120 is grown on a top surface thereof

In the present invention, the first substrate 111 and the second substrate 112 are provided as sapphire substrates. The sapphire substrate is an optically transparent and high-temperature heat-resistant substrate through which 100% of a laser beam (single wavelength light) may pass without absorption (theoretically) in a laser lift-off (LLO) process, which will be described below, and may be provided as α-phase Al₂O₃ sapphire (containing ScAlMgO₄).

Here, when the semiconductor layer 120 emits blue or green light, the first substrate 111 serves as a growth sapphire substrate and should be positioned so that a surface on which the semiconductor layer 120 made of a Group-III nitride, such as GaN, is grown becomes an upper surface, and it is required that both surfaces are polished at a high quality level to be optically transparent.

In addition, the second substrate 112 serves as a carrier sapphire substrate and does not require relatively high quality compared to the first substrate 111, but both surfaces should be polished and optically transparent, and a sacrificial separation layer 112a may be provided on the second substrate 112.

Here, the sacrificial separation layer 112a is a layer that is sacrificed and separated when the second substrate 112 is separated using the LLO technique which will be described below. The sacrificial separation layer 112a is formed of a material that enables sacrificial separation by a thermal-chemical decomposition reaction and may be formed of, for example, materials such as ITO, IGZO, ZnO, TiN, InGaN, GaN, InGaON, GaON, SiO₂, SiNₓ, etc., but the present invention is not limited thereto.

Meanwhile, when the semiconductor layer 120 of the present invention emits blue or green light, the semiconductor layer 120 may have a structure in which binary, ternary, or quaternary compounds such as InN, InGaN, GaN, AlGaN, AlN, AlGaInN, etc. which are Group-III (Al, Ga, and In) nitride semiconductors, are epitaxially grown in appropriate positions and orders on the first substrate 111.

In addition, in order to minimize crystal defects inside the epitaxial thin film of the Group-III nitride semiconductor layer 120 grown on the top, the first substrate 111 may have a protrusion shape that is regularly or irregularly patterned with various microscale or nanoscale dimensions (sizes and shapes).

In addition, when the semiconductor layer 120 of the present invention emits red light, binary, ternary, and quaternary compounds such as InP, InGaP, GaP, AlInP, AlGaP, AlP, AlGaInP, which are Group-III (Al, Ga, and In) phosphide semiconductors, are epitaxy grown on a GaAs initial growth substrate in appropriate positions and orders, the initial growth substrate is removed using an intermediate temporary substrate, and then the first substrate 111, which is a sapphire substrate, is bonded to a removal surface of the initial growth substrate so that the semiconductor layer 120 may have a structure in which the GaAs growth substrate is replaced with a sapphire substrate. Since the subsequent process is the same, the following description will be made based on a case in which the semiconductor layer 120 is a Group-III nitride semiconductor.

More specifically, the semiconductor layer 120 includes a first semiconductor region 121 (e.g., a p-type semiconductor region), an active region 123 (e.g., multi quantum wells (MQWs)), and a second semiconductor region 122 (e.g., an n-type semiconductor region) and may include a structure in which the second semiconductor region 122, the active region 123, and the first semiconductor region 121 are epitaxially grown on the first substrate 111 in this order and may ultimately have a thickness of about 5.0 μm to 8.0 μm generally, including several multi-layered Group-III nitrides, but the present invention is not limited thereto.

Each of the first semiconductor region 121, the active region 123, and the second semiconductor region 122 may be formed of a single layer or multiple layers, and although not shown in the drawings, prior to epitaxially growing the semiconductor layer 120 on the first substrate 111, in order to improve the quality of the epitaxially grown semiconductor layer 120, necessary layers such as a buffer region may be added. For example, the buffer region may be formed to have a thickness of typically about 4.0 μm, including a compliant layer consisting of a nucleation layer and an undoped semiconductor region for stress relief and thin-film quality improvement. In addition, when the first substrate 111 is removed using the LLO technique, the sacrificial separation layer 112a may be provided between the nucleation layer and the undoped semiconductor region, and a seed layer may function as the sacrificial separation layer 112a.

The second semiconductor region 122 has a second conductivity (n-type) and is formed on the first substrate 111. The second semiconductor region 122 may have a thickness of 2.0 μm to 3.5 μm.

The active region 123 generates light by utilizing recombination of electrons and holes and is formed on the second semiconductor region 122. The active region 123 may have a thickness of several tens of nm in a multilayer mainly formed of InGaN and GaN semiconductors.

The first semiconductor region 121 has a first conductivity (p-type) and is formed on the active region 123. The first semiconductor region 121 may have a thickness of several tens of nm to several micrometers in a multilayer mainly formed of AlGaN and GaN semiconductors, and an upper surface has Ga polarity.

That is, the active region 123 is interposed between the first semiconductor region 121 and the second semiconductor region 122, and when holes in the first semiconductor region 121 that is a p-type semiconductor region and electrons in the second semiconductor region 122 that is an n-type semiconductor region recombine in the active region 123, light is generated.

The electrode formation operation S120 is an operation of forming an electrode 130 on the semiconductor layer 120 by performing a fab process on the semiconductor layer 120.

That is, in the electrode formation operation S120, the fab process is performed such that the semiconductor layer 120 is etched (mesa etching) according to the structure of the semiconductor light-emitting device, such as a lateral chip, a flip chip, or a vertical chip, an ohmic contact electrode 130 (at least one of a p-type ohmic electrode and an n-type ohmic electrode) electrically connected to the semiconductor layer 120 is formed, and then a passivation layer P covering at least a portion of the semiconductor layer 120 or the electrode 130 is formed.

In this case, the ultra-thin type semiconductor die manufactured by the method S100 of manufacturing an ultra-thin type semiconductor die according to the first embodiment of the present invention may have a structure in which only the p-type ohmic electrode is formed as shown in FIG. 4, may have a structure in which both the p-type ohmic electrode and the n-type ohmic electrode are formed after a portion of the semiconductor layer 120 is mesa-etched as shown in FIG. 5, or may have a structure in which a bonding pad layer B is formed on the ohmic electrode, but the present invention is not limited to these structures. In addition, an ultra-thin type semiconductor die manufactured by a method of manufacturing an ultra-thin type semiconductor die according to second to fourth embodiments, which will be described below, may have an identical or similar structure in terms of the semiconductor layer 120 and an upper structure of the semiconductor layer 120.

Meanwhile, a material with high optical transparency or optical reflection is suitable for the electrode 130, and annealing may be performed in order to minimize electrical resistance at an interface between materials. In addition, examples of optically transparent materials may include ITO, IGZO, ZnO, TiN, Ni(O)—Au, etc., examples of optically reflective materials may include Ag, Al, Rh, Ni, DBR(SiO₂/TiO₂), etc., and the optically transparent materials and the optically reflective materials may be combined, but the present invention is not limited thereto.

The bonding operation S130 is an operation of forming a protective layer 140 to cover the electrode 130 and bonding the second substrate 112 to the protective layer 140 through a bonding layer 150.

As smaller dies (epitaxial dies or chip dies) are required for manufacturing mini or micro level semiconductor light-emitting devices, a process technology for a thinner sapphire is required.

In this case, when a thickness of the sapphire growth substrate is formed to be thin from the beginning or when the Group-III nitride semiconductor is grown, or when the group III nitride semiconductor is grown, and immediately after, the thickness of the sapphire growth substrate is formed to be thin, a problem occurs in which the die or wafer is deformed and damaged due to thermo-mechanical induced stress generated by a difference in a lattice constant (LC) and a coefficient of thermal expansion (CTE) between the sapphire growth substrate and the Group-III nitride semiconductor during the shaping process.

Accordingly, according to the present invention, before the first substrate 111, which is a sapphire substrate, is shaped into an ultra-thin shape, the protective layer 140 is formed to cover the semiconductor layer 120 and/or the electrode 130 and then the second substrate 112, which is the same sapphire substrate, is bonded to the protective layer 140 through the bonding layer 150 so that the problem of a wafer being damaged due to thermo-mechanical induced stress generated by a difference in LC and CTE between the thin sapphire growth substrate and the Group-III nitride semiconductor can be solved After the first substrate 111 is shaped into an ultra-thin shape, the thick second substrate 112 is removed to enable the manufacture of a small die (epitaxial die or chip die) having a thickness of less than 50 μm.

Here, the protective layer 140 serves to protect the device structure, and may include, for example, SiO₂, SiNₓ, AlN, Al₂O₃, etc., but the present invention is not limited thereto.

In addition, various bonding methods such as metal bonding, adhesive bonding, and direct bonding may be applied to the bonding layer 150, but the present invention is not limited thereto, and a method that has a strong bonding force and may perform bonding at the lowest possible temperature so as to suppress a bow phenomenon of the epitaxy wafer as much as possible.

The shaping operation S140 is an operation of shaping the first substrate 111 into an ultra-thin shape.

In this case, in order to enable the manufacture of a small die (epitaxial die or chip die) with a thickness of less than 50 μm, which was previously impossible, the thickness of the first sapphire substrate 111 may be shaped to have a thickness of less than 50 μm.

More specifically, the first sapphire substrate 111 is subjected to a lapping process in which mechanical polishing is performed at high speed, and then a mechanical polishing process is performed to allow the first substrate 111 to have an accurate, ultra-thin final thickness. Thereafter, as necessary, as a final shaping operation, the shaping process is completed by performing a chemical mechanical polishing (CMP) process to allow a surface of the first substrate 111 to have surface roughness of 0.5 nm or less. However, the present invention is not limited to the above-described processes and is not limited as long as it is for shaping the first substrate 111 to have the final thickness.

In addition, as necessary, in order to improve the quality of the epitaxial thin film of the Group-III nitride semiconductor layer 120 and maximize light extraction efficiency after the CMP process is completed, it is preferable to have a protrusion shape that is regularly or irregularly patterned on the upper surface of the first sapphire substrate 111 in various microscale or nanoscale dimensions (sizes and shapes).

The guide groove formation operation S150 is an operation of forming a guide groove G on the surface of or inside the ultra-thin type shaped first substrate 111 using a laser beam.

Here, the concept of the guide groove G includes a guide groove, a guide path, a crack, a notch, etc. formed on the surface of or inside the first substrate 111 formed into an ultra-thin shape, and when the second substrate 112 is separated and removed using the LLO technique in a subsequent process, the guide groove G serves to guide a cut surface when the first substrate 111 is cut (diced) by relieving the residual stress present in the first substrate 111.

More specifically, in order to cut and separate the semiconductor layer 120 into die units in the removal operation S160 which will be described below, a guide groove G may be generated in the surface of or inside each of a plurality of regions of the first substrate 111 formed in an ultra-thin shape through a process such as laser scribing, laser ablation, or patterning & plasma dry etching in the guide groove formation operation S150.

The removal operation S160 is an operation of removing the second substrate 112 and removing the bonding layer 150 and the protective layer 140.

In this case, in the removal operation S160, a carrier tape T (a tape, such as a blue tape or an ultraviolet (UV) tape, that is picked and placed) is attached to the first substrate 111 shaped into an ultra-thin shape, the second substrate 112 is removed using the LLO technique, and then the remaining sacrificial separation layer 112a, the bonding layer 150, and the protective layer 140 are etched and removed.

Here, the LLO technique is a technique for separating the second substrate 112 by emitting a UV laser beam, which has a uniform optical output, a uniform beam profile, and a single wavelength, to a rear surface of a transparent growth substrate. Alternatively, the second substrate 112 may also be separated using a chemical lift off (CLO) technique.

Further, in the removal operation S160, since the thick second substrate 112 is removed, the thermo-mechanical induced stress, i.e., a residual stress effect, (wafer bow or breakage occurs) generated due to the difference in LC and CTE occurs in the thin first sapphire substrate 111 and the semiconductor layer 120.

In this case, when the guide groove G is formed in the surface of or inside the first substrate 111, which is shaped into an ultra-thin shape, through a laser beam in the shaping operation S140, cracks propagate to the semiconductor layer 120 and the electrode 130 only in corresponding portions in which the guide groove G is formed due to the thermo-mechanical induced stress, and thus the first substrate 111, the semiconductor layer 120, and the electrode 130 may be cut and separated into die units due to the propagating cracks. That is, in the present invention, the guide groove G may serve as a guide when the die is separated.

Meanwhile, after the cutting process, complete separation (or spacing) between dies (or between chips) may be achieved through expansion of the carrier tape T in all directions.

Hereinafter, with reference to the accompanying drawings, a method S200 of manufacturing an ultra-thin type semiconductor die according to a second embodiment of the present invention will be described in detail.

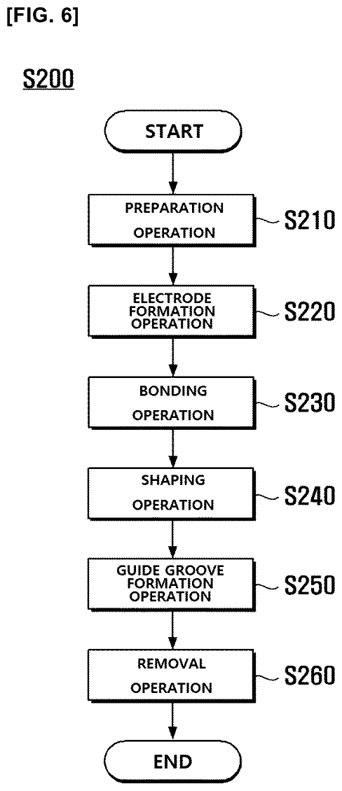

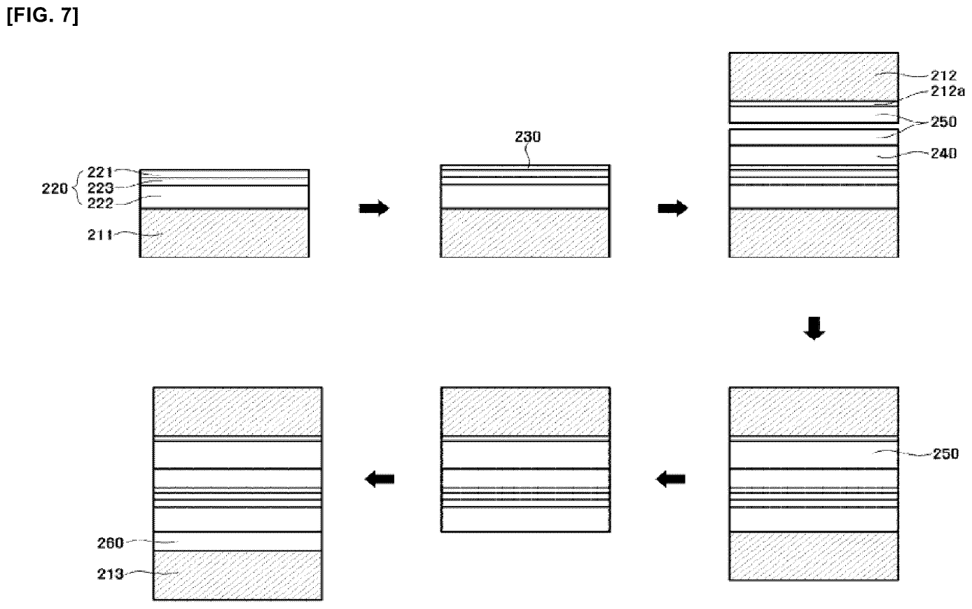

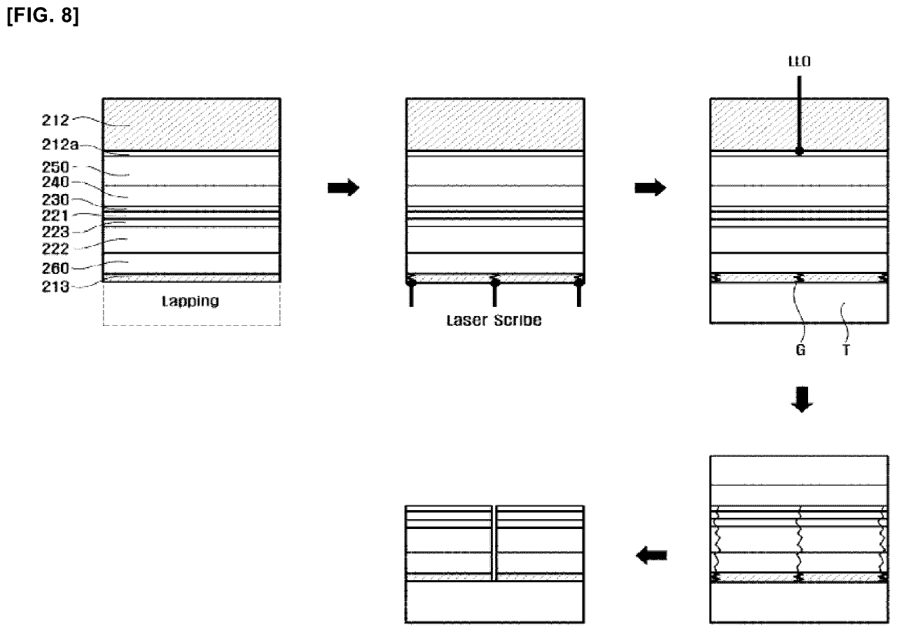

FIG. 6 is a flowchart illustrating the method S200 of manufacturing an ultra-thin type semiconductor die according to the second embodiment of the present invention, and FIGS. 7 and 8 are diagrams illustrating a process of manufacturing an ultra-thin type semiconductor die by the method S200 of manufacturing an ultra-thin type semiconductor die according to the second embodiment of the present invention.

As shown in FIGS. 6 to 8, the method S200 of manufacturing an ultra-thin type semiconductor die according to the second embodiment of the present invention is for manufacturing a small die (epitaxial die or chip die) having a thickness of less than 50 μm, which was previously impossible, and includes a preparation operation S210, an electrode formation operation S220, a bonding operation S230, a shaping operation S240, a guide groove formation operation S250, and a removal operation S260.

The preparation operation S210 is an operation of preparing a first substrate 211, a second substrate 212, and a third substrate 213 and is an operation of preparing the first substrate 211 on which the semiconductor layer 220 is grown on a top surface.

In the present invention, the first substrate 211, the second substrate 212, and the third substrate 213 are provided as sapphire substrates. The sapphire substrate is an optically transparent and high-temperature heat-resistant substrate through which 100% of a laser beam (single wavelength light) may pass without absorption (theoretically) in a laser lift-off (LLO) process, which will be described below, and may be provided as α-phase Al₂O₃ sapphire (containing ScAlMgO₄).

The following contents of the preparation operation S210 to the electrode formation operation S220 are the same as those of the method of manufacturing an ultra-thin type semiconductor die according to the first embodiment of the present invention, and thus a duplicate description will be omitted.

The bonding operation S230 is an operation of forming a protective layer 240 to cover the electrode 230 and bonding the second substrate 212 to the protective layer 240 through a bonding layer 250.

As smaller dies (epitaxial dies or chip dies) are required for manufacturing mini or micro level semiconductor light-emitting devices, a process technology for a thinner sapphire is required.

In this case, when a thickness of the sapphire growth substrate is formed to be thin from the beginning or when the Group-III nitride semiconductor is grown, or when the group III nitride semiconductor is grown, and immediately after, the thickness of the sapphire growth substrate is formed to be thin, a problem occurs in which the die or wafer is deformed and damaged due to thermo-mechanical induced stress generated by a difference in an LC and a CTE between the sapphire growth substrate and the Group-III nitride semiconductor during the shaping process.

Accordingly, according to the present invention, before the third substrate 213, which is a sapphire substrate, is shaped into an ultra-thin shape, the protective layer 240 is formed to cover the semiconductor layer 220 and/or the electrode 230 and then the second substrate 212, which is the same sapphire substrate, is bonded to the protective layer 240 through the bonding layer 250 so that the problem of a wafer being damaged due to thermo-mechanical induced stress generated by a difference in LC and CTE between the thin sapphire growth substrate and the Group-III nitride semiconductor can be solved After the third substrate 213 is shaped into an ultra-thin shape, the thick second substrate 212 is removed to enable the manufacture of a small die (epitaxial die or chip die) having a thickness of less than 50 μm.

Here, the protective layer 240 serves to protect the device structure, and may include, for example, SiO₂, SiNₓ, AlN, Al₂O₃, etc., but the present invention is not limited thereto.

In addition, various bonding methods such as metal bonding, adhesive bonding, and direct bonding may be applied to the bonding layer 250, but the present invention is not limited thereto, and a method that has a strong bonding force and may perform bonding at the lowest possible temperature so as to suppress a bow phenomenon of the epitaxy wafer as much as possible.

The shaping operation S240 is an operation of removing the first substrate 211 to expose the semiconductor layer 220, bonding the third substrate 213 to the exposed semiconductor layer 220 through the bonding layer 260, and then shaping the third substrate 213 into an ultra-thin shape.

In this case, in order to enable the manufacture of a small die (epitaxial die or chip die) with a thickness of less than 50 μm, which was previously impossible, the thickness of the third sapphire substrate 213 may be shaped to have a thickness of less than 50 μm.

More specifically, the third sapphire substrate 213 is subjected to a lapping process in which mechanical polishing is performed at high speed, and then a mechanical polishing process is performed to allow the third substrate 213 to have an accurate, ultra-thin final thickness. Thereafter, as necessary, as a final shaping operation, the shaping process is completed by performing a CMP process to allow a surface of the third substrate 213 to have surface roughness of 0.5 nm or less. However, the present invention is not limited to the above-described processes and is not limited as long as it is for shaping the third substrate 213 to have the final thickness.

In addition, as necessary, in order to improve the quality of the epitaxial thin film of the Group-III nitride semiconductor layer 220 and maximize light extraction efficiency after the CMP process is completed, it is preferable to have a protrusion shape that is regularly or irregularly patterned on the upper surface of the third sapphire substrate 213 in various microscale or nanoscale dimensions (sizes and shapes).

The guide groove formation operation S250 is an operation of forming a guide groove G on the surface of or inside the ultra-thin type shaped third substrate 213 using a laser beam.

Here, the concept of the guide groove G includes a guide groove, a guide path, a crack, a notch, etc., formed on the surface of or inside the third substrate 213 formed into an ultra-thin shape, and when the second substrate 212 is separated and removed using the LLO technique in a subsequent process, the guide groove G serves to guide a cut surface when the third substrate 213 is cut (diced) by relieving the residual stress present in the third substrate 213.

More specifically, in order to cut and separate the third substrate 213 and the semiconductor layer 220 into die units in the removal operation S260 which will be described below, a guide groove G may be generated in the surface of or inside each of a plurality of regions of the third substrate 213 formed in an ultra-thin shape through a process such as laser scribing, laser ablation, or patterning & plasma dry etching in the guide groove formation operation S250.

The removal operation S260 is an operation of removing the second substrate 212 and removing the bonding layer 250 and the protective layer 240.

In this case, in the removal operation S260, a carrier tape T (a tape, such as a blue tape or an ultraviolet (UV) tape, that is picked and placed) is attached to the third substrate 213 shaped into an ultra-thin shape, the second substrate 212 is removed using the LLO technique, and then the remaining sacrificial separation layer 212a, the bonding layer 250, and the protective layer 240 are etched and removed.

Here, the LLO technique is a technique for separating the second substrate 212 by emitting a UV laser beam, which has a uniform optical output, a uniform beam profile, and a single wavelength, to a rear surface of a transparent growth substrate. Alternatively, the second substrate 212 may also be separated using a CLO technique.

Further, in the removal operation S260, since the thick second substrate 212 is removed, the thermo-mechanical induced stress, i.e., a residual stress effect, generated due to the difference in an LC and a CTE occurs (i.e., wafer bow or breakage occurs) in the thin third sapphire substrate 213 and the semiconductor layer 220.

In this case, when the guide groove G is formed in the surface of or inside the third substrate 213, which is shaped into an ultra-thin shape, through a laser beam in the shaping operation S240, cracks propagate to the bonding layer 260, the semiconductor layer 220 and the electrode 230 only in corresponding portions in which the guide groove G is formed due to the thermo-mechanical induced stress, and thus the third substrate 213, the bonding layer 260, the semiconductor layer 220, and the electrode 230 may be cut and separated into die units due to the propagating cracks. That is, in the present invention, the guide groove G may serve as a guide when the die is separated.

Meanwhile, after the cutting process, complete separation (or spacing) between dies (or between chips) may be achieved through expansion of the carrier tape T in all directions.

Hereinafter, with reference to the accompanying drawings, a method S300 of manufacturing an ultra-thin type semiconductor die according to a third embodiment of the present invention will be described in detail.

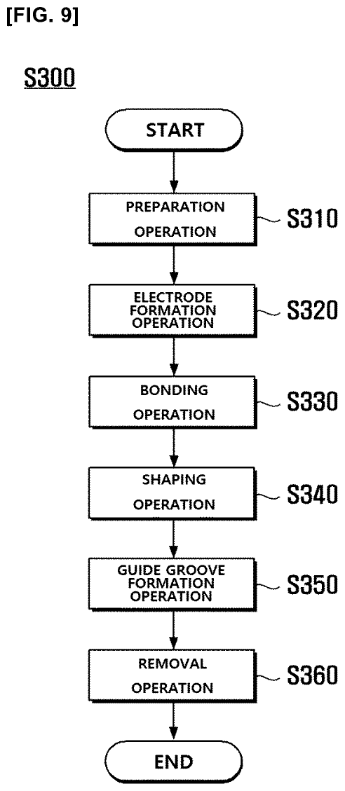

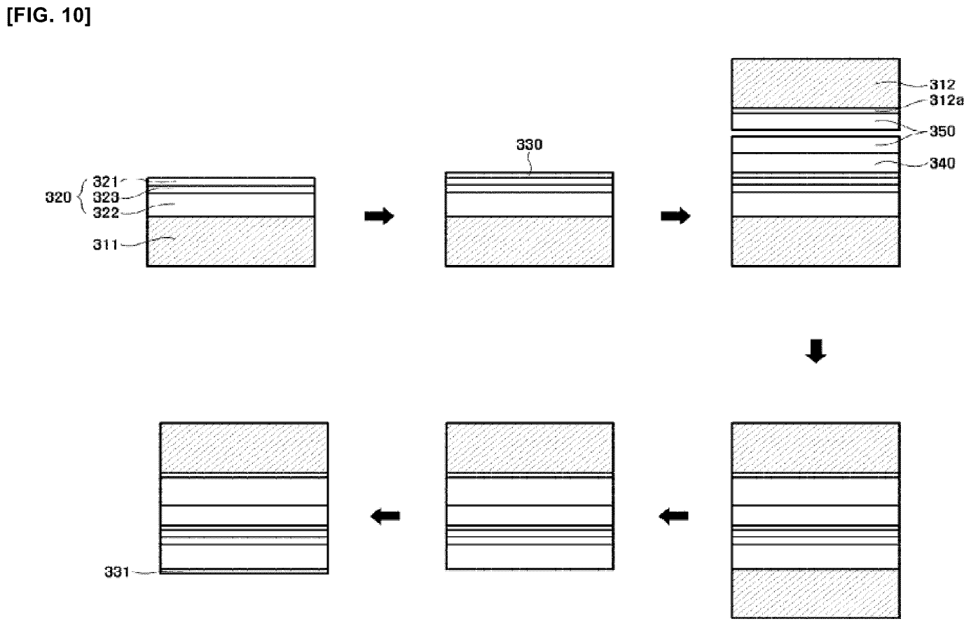

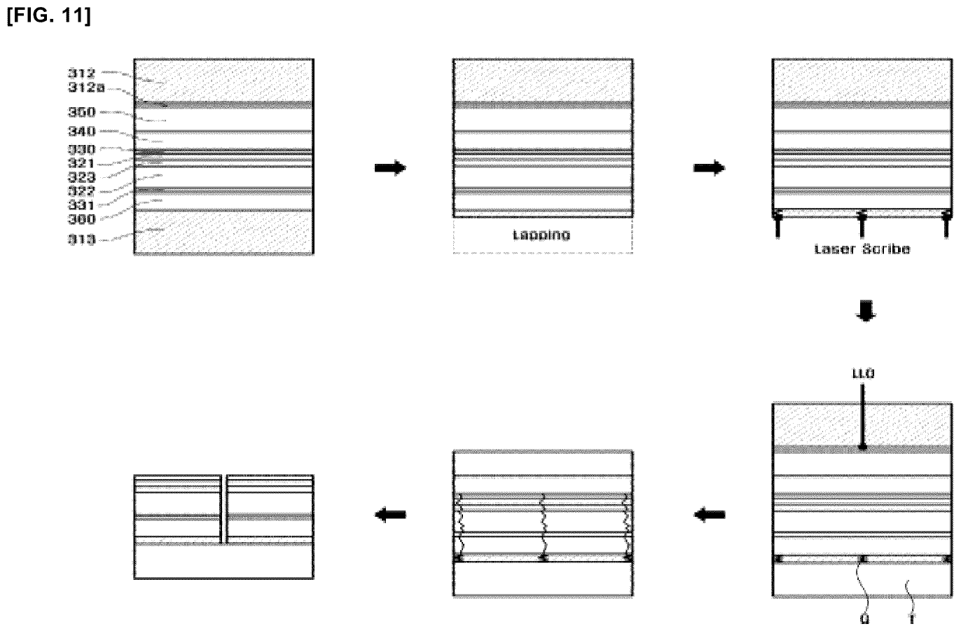

FIG. 9 is a flowchart illustrating the method S300 of manufacturing an ultra-thin type semiconductor die according to the third embodiment of the present invention, and FIGS. 10 and 11 are diagrams illustrating a process of manufacturing an ultra-thin type semiconductor die by the method S300 of manufacturing an ultra-thin type semiconductor die according to the third embodiment of the present invention.

As shown in FIGS. 9 to 11, the method S300 of manufacturing an ultra-thin type semiconductor die according to the third embodiment of the present invention is for manufacturing a small die (epitaxial die or chip die) having a thickness of less than 50 μm, which was previously impossible, and includes a preparation operation S310, an electrode formation operation S320, a bonding operation S330, a shaping operation S340, a guide groove formation operation S350, and a removal operation S360.

The preparation operation S310 is an operation of preparing a first substrate 311, a second substrate 312, and a third substrate 313 and is an operation of preparing the first substrate 311 on which the semiconductor layer 320 is grown on a top surface thereof.

In the present invention, the first substrate 311, the second substrate 312, and the third substrate 313 are provided as sapphire substrates. The sapphire substrate is an optically transparent and high-temperature heat-resistant substrate through which 100% of a laser beam (single wavelength light) may pass without absorption (theoretically) in a laser lift-off (LLO) process, which will be described below, and may be provided as α-phase Al₂O₃ sapphire (containing ScAlMgO₄).

The following contents of the preparation operation S310 to the electrode formation operation S320 are the same as those of the method of manufacturing an ultra-thin type semiconductor die according to the first embodiment of the present invention, and thus a duplicate description will be omitted.

The bonding operation S330 is an operation of forming a protective layer 340 to cover the electrode 330 and bonding the second substrate 312 to the protective layer 340 through a bonding layer 350.

As smaller dies (epitaxial dies or chip dies) are required for manufacturing mini or micro level semiconductor light-emitting devices, a process technology for a thinner sapphire substrate is required.

In this case, when a thickness of the sapphire growth substrate is formed to be thin from the beginning or when the Group-III nitride semiconductor is grown, or when the group III nitride semiconductor is grown, and immediately after, the thickness of the sapphire growth substrate is formed to be thin, a problem occurs in which the die or wafer is deformed and damaged due to thermo-mechanical induced stress generated by a difference in an LC and a CTE between the sapphire growth substrate and the Group-III nitride semiconductor during the shaping process.

Accordingly, according to the present invention, before the third substrate 313, which is a sapphire substrate, is shaped into an ultra-thin shape, the protective layer 340 is formed to cover the semiconductor layer 320 and/or the electrode 330 and then the second substrate 312, which is the same sapphire substrate, is bonded to the protective layer 340 through the bonding layer 350 so that the problem of a wafer being damaged due to thermo-mechanical induced stress generated by a difference in LC and CTE between the thin sapphire growth substrate and the Group-III nitride semiconductor can be solved After the third substrate 313 is shaped into an ultra-thin shape, the thick second substrate 312 is removed to enable the manufacture of a small die (epitaxial die or chip die) having a thickness of less than 50 μm.

Here, the protective layer 340 serves to protect the device structure, and may include, for example, SiO₂, SiNₓ, AlN, Al₂O₃, etc., but the present invention is not limited thereto.

In addition, various bonding methods such as metal bonding, adhesive bonding, and direct bonding may be applied to the bonding layer 350, but the present invention is not limited thereto, and a method that has a strong bonding force and may perform bonding at the lowest possible temperature so as to suppress a bow phenomenon of the epitaxy wafer as much as possible.

The shaping operation S340 is an operation of removing the first substrate 311 to expose the semiconductor layer 320, forming a lower electrode 331 on the exposed semiconductor layer 320, bonding the third substrate 313 to the lower electrode 331 through the bonding layer 360, and then shaping the third substrate 313 into an ultra-thin shape.

In this case, the lower electrode 331 may be an ohmic electrode in ohmic contact with the semiconductor layer 320, and when the electrode 330 on the semiconductor layer 320 is a p-type ohmic electrode, the lower electrode 331 may be formed as an n-type ohmic electrode, and when the electrode 330 on the semiconductor layer 320 is an n-type ohmic electrode, the lower electrode 331 may be formed as a p-type ohmic electrode.

In addition, in order to enable the manufacture of a small die (epitaxial die or chip die) with a thickness of less than 50 μm, which was previously impossible, the thickness of the third sapphire substrate 313 may be shaped to have a thickness of less than 50 μm.

More specifically, the third sapphire substrate 313 is subjected to a lapping process in which mechanical polishing is performed at high speed, and then a mechanical polishing process is performed to allow the third substrate 313 to have an accurate, ultra-thin final thickness. Thereafter, as necessary, as a final shaping operation, the shaping process is completed by performing a CMP process to allow a surface of the third substrate 313 to have surface roughness of 0.5 nm or less. However, the present invention is not limited to the above-described processes and is not limited as long as it is for shaping the third substrate 313 to have the final thickness.

In addition, as necessary, in order to improve the quality of the epitaxial thin film of the Group-III nitride semiconductor layer 320 and maximize light extraction efficiency after the CMP process is completed, it is preferable to have a protrusion shape that is regularly or irregularly patterned on the upper surface of the third sapphire substrate 313 in various microscale or nanoscale dimensions (sizes and shapes).

The guide groove formation operation S350 is an operation of forming a guide groove G in the surface of or inside the ultra-thin type shaped third substrate 313 using a laser beam.

Here, the concept of the guide groove G includes a guide groove, a guide path, a crack, a notch, etc., formed on the surface of or inside the third substrate 313 formed into an ultra-thin shape, and when the second substrate 312 is separated and removed using the LLO technique in a subsequent process, the guide groove G serves to guide a cut surface when the third substrate 313 is cut (diced) by relieving the residual stress present in the third substrate 313.

More specifically, in order to cut and separate the third substrate 313 and the semiconductor layer 320 into die units in the removal operation S360 which will be described below, a guide groove G may be generated on the surface of or inside each of a plurality of regions of the third substrate 313 formed in an ultra-thin shape through a process such as laser scribing, laser ablation, or patterning & plasma dry etching in the guide groove formation operation S350.

The removal operation S360 is an operation of removing the second substrate 312 and removing the bonding layer 350 and the protective layer 340.

In this case, in the removal operation S360, a carrier tape T (a tape, such as a blue tape or a UV tape, that is picked and placed) is attached to the third substrate 313 shaped into an ultra-thin shape, the second substrate 312 is removed using the LLO technique, and then the remaining sacrificial separation layer 312a, the bonding layer 350, and the protective layer 340 are etched and removed.

Here, the LLO technique is a technique for separating the second substrate 312 by emitting a UV laser beam, which has a uniform optical output, a uniform beam profile, and a single wavelength, to a rear surface of a transparent growth substrate. Alternatively, the second substrate 312 may also be separated using a CLO technique.

Further, in the removal operation S360, since the thick second substrate 312 is removed, the thermo-mechanical induced stress, i.e., a residual stress effect, (wafer bow or breakage occurs) generated due to the difference in an LC and a CTE occurs in the thin third sapphire substrate 313 and the semiconductor layer 320.

In this case, when the guide groove G is formed in the surface of or inside the third substrate 313, which is shaped into an ultra-thin shape, through a laser beam in the shaping operation S340, cracks propagate to the lower electrode 331, the semiconductor layer 320, and the electrode 330 only in corresponding portions in which the guide groove G is formed due to the thermo-mechanical induced stress, and thus the third substrate 313, the bonding layer 360, the lower electrode 331, the semiconductor layer 320, and the electrode 330 may be cut and separated into die units due to the propagating cracks. That is, in the present invention, the guide groove G may serve as a guide when the die is separated.

Meanwhile, after the cutting process, complete separation (or spacing) between dies (or between chips) may be achieved through expansion of the carrier tape T in all directions.

Hereinafter, with reference to the accompanying drawings, a method S400 of manufacturing an ultra-thin type semiconductor die according to a fourth embodiment of the present invention will be described in detail.

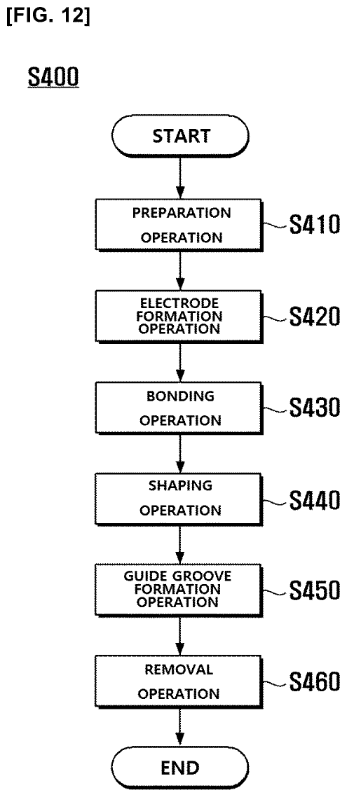

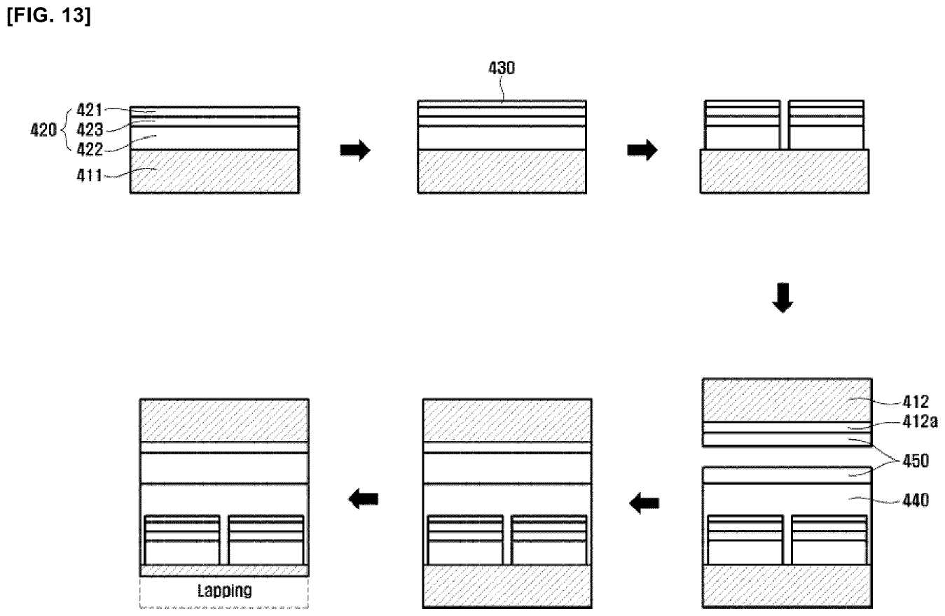

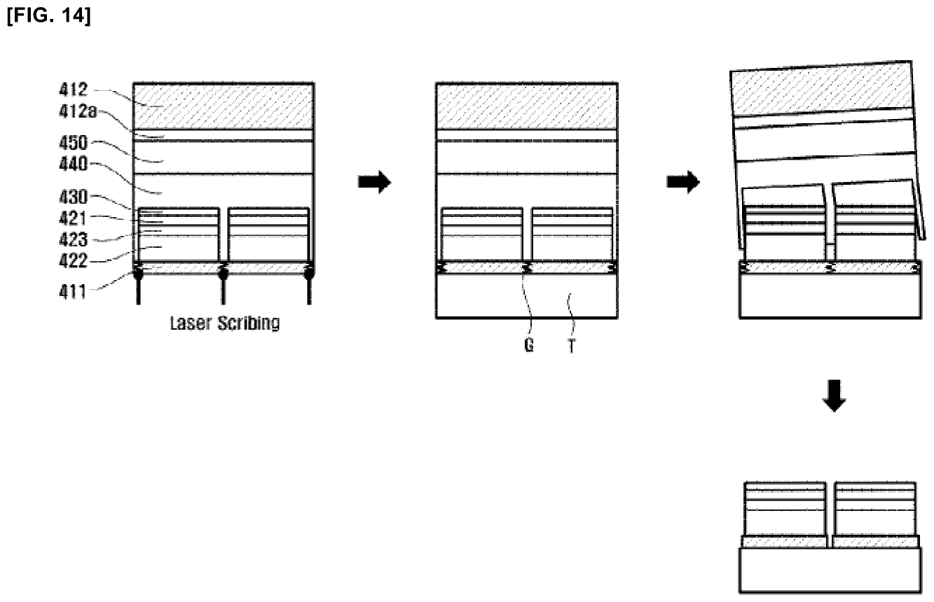

FIG. 12 is a flowchart illustrating the method S400 of manufacturing an ultra-thin type semiconductor die according to the fourth embodiment of the present invention, and FIGS. 13 and 14 are diagrams illustrating a process of manufacturing an ultra-thin type semiconductor die by the method S400 of manufacturing an ultra-thin type semiconductor die according to the fourth embodiment of the present invention.

As shown in FIGS. 12 to 14, the method S400 of manufacturing an ultra-thin type semiconductor die according to the fourth embodiment of the present invention is for manufacturing a small die (epitaxial die or chip die) having a thickness of less than 50 μm, which was previously impossible, and includes a preparation operation S410, an electrode formation operation S420, a bonding operation S430, a shaping operation S440, a guide groove formation operation S450, and a removal operation S460.

The preparation operation S410 is an operation of preparing a first substrate 411 and the second substrate 412 and is an operation of preparing the first substrate 411 on which the semiconductor layer 420 is grown on a top surface thereof.

In the present invention, the first substrate 411 and the second substrate 412 are provided as sapphire substrates. The sapphire substrate is an optically transparent and high-temperature heat-resistant substrate through which 100% of a laser beam (single wavelength light) may pass without absorption (theoretically) in a laser lift-off (LLO) process, which will be described below, can be provided as α-phase Al₂O₃ sapphire (containing ScAlMgO₄).

The following contents of the preparation operation S410 to the electrode formation operation S420 are the same as those of the method of manufacturing an ultra-thin type semiconductor die according to the first embodiment of the present invention, and thus a duplicate description will be omitted.

The bonding operation S430 is an operation of etching and separating the semiconductor layer 420 and the electrode 430 into die units, forming a protective layer 440 to cover or surround the separated semiconductor layer 420 and the separated electrode 430, and bonding the second substrate 412 to the protective layer 440 through a bonding layer 450.

As smaller dies (epitaxial dies or chip dies) are required for manufacturing mini or micro level semiconductor light-emitting devices, a process technology for a thinner sapphire substrate is required.

In this case, when a thickness of the sapphire growth substrate is formed to be thin from the beginning or when the Group-III nitride semiconductor is grown, or when the group III nitride semiconductor is grown, and immediately after, the thickness of the sapphire growth substrate is formed to be thin, a problem occurs in which the die or wafer is deformed and damaged due to thermo-mechanical induced stress generated by a difference in an LC and a CTE between the sapphire growth substrate and the Group-III nitride semiconductor during the shaping process.

Accordingly, according to the present invention, before the first substrate 411, which is a sapphire substrate, is shaped into an ultra-thin shape, and after the semiconductor layer 420 and the electrode 430 are etched first, the protective layer 440 is formed to cover the semiconductor layer 420 and/or the electrode 430 and then the second substrate 412, which is the same sapphire substrate, is bonded to the protective layer 440 through the bonding layer 450 so that the problem of a wafer being damaged due to thermo-mechanical induced stress generated by a difference in an LC and a CTE between the thin sapphire growth substrate and the Group-III nitride semiconductor can be solved After the first substrate 411 is shaped into an ultra-thin shape, the thick second substrate 412 is removed to enable the manufacture of a small die (epitaxial die or chip die) having a thickness of less than 50 μm.

Here, the protective layer 440 serves to protect the device structure, and may include, for example, SiO₂, SiNₓ, AlN, Al₂O₃, etc., but the present invention is not limited thereto.

In addition, various bonding methods such as metal bonding, adhesive bonding, and direct bonding may be applied to the bonding layer 450, but the present invention is not limited thereto, and a method that has a strong bonding force and may perform bonding at the lowest possible temperature so as to suppress a bow phenomenon of the epitaxy wafer as much as possible.

The shaping operation S440 is an operation of shaping the first substrate 411 into an ultra-thin shape.

In this case, in order to enable the manufacture of a small die (epitaxial die or chip die) with a thickness of less than 50 μm, which was previously impossible, the thickness of the first sapphire substrate 411 may be shaped to have a thickness of less than 50 μm.

More specifically, the first sapphire substrate 411 is subjected to a lapping process in which mechanical polishing is performed at high speed, and then a mechanical polishing process is performed to allow the first substrate 411 to have an accurate, ultra-thin final thickness. Thereafter, as necessary, as a final shaping operation, the shaping process is completed by performing a chemical mechanical polishing (CMP) process to allow a surface of the first substrate 411 to have surface roughness of 0.5 nm or less. However, the present invention is not limited to the above-described processes and is not limited as long as it is for shaping the first substrate 411 to have the final thickness.

In addition, as necessary, in order to improve the quality of the epitaxial thin film of the Group-III nitride semiconductor layer 420 and maximize light extraction efficiency after the CMP process is completed, it is preferable to have a protrusion shape that is regularly or irregularly patterned on the upper surface of the third sapphire substrate in various microscale or nanoscale dimensions (sizes and shapes).

The guide groove formation operation S450 is an operation of forming a guide groove G on the surface of or inside the ultra-thin type shaped first substrate 411 using a laser beam.

Here, the concept of the guide groove G includes a guide groove, a guide path, a crack, a notch, etc., formed on the surface of or inside the first substrate 411 formed into an ultra-thin shape, and when the second substrate 412 is separated and removed using the LLO technique in a subsequent process, the guide groove G serves to guide a cut surface when the first substrate 411 is cut (diced) by relieving the residual stress present in the first substrate 411.

More specifically, in order to cut and separate the first substrate 411 into die units in the removal operation S460 which will be described below, a guide groove G may be generated in the surface of or inside each of a plurality of regions of the first substrate 411 in an ultra-thin shape through a process such as laser scribing, laser ablation, or patterning & plasma dry etching in the guide groove formation operation S450.

The removal operation S460 is an operation of removing the second substrate 412 and removing the bonding layer 450 and the protective layer 440.

In this case, in the removal operation S460, a carrier tape T (a tape, such as a blue tape or a UV tape, that is picked and placed) is attached to the first substrate 411 shaped into an ultra-thin shape, the protective layer 440 is dissolved and then the second substrate 412, the bonding layer 450, and the protective layer 440 are removed simultaneously, the second substrate 412 is removed using the LLO technique, and then the remaining sacrificial separation layer 412a, the bonding layer 450, and the protective layer 440 are etched and removed.

Here, the LLO technique is a technique for separating the second substrate 412 by emitting a UV laser beam, which has a uniform optical output, a uniform beam profile, and a single wavelength, to a rear surface of a transparent growth substrate. Alternatively, the second substrate 412 may also be separated using a CLO technique.

Further, in the removal operation S460, since the thick second substrate 412 is removed, the thermo-mechanical induced stress generated due to a difference in an LC and a CTE occurs in the thin first sapphire substrate 411 and the semiconductor layer 420 (wafer occurs).

In this case, when the guide groove G is formed in the surface of or inside the first substrate 411, which is shaped into an ultra-thin shape, through a laser beam in the shaping operation S440, cracks propagate to corresponding portions in which the guide groove G is formed due to the thermo-mechanical induced stress, and thus the first substrate 411 may be cut and separated into die units due to the propagating cracks. That is, in the present invention, the guide groove G may serve as a guide when the die is separated.

Meanwhile, after the cutting process, complete separation (or spacing) between dies (or between chips) may be achieved through expansion of the carrier tape T in all directions.

Hereinafter, with reference to the accompanying drawings, a method S500 of manufacturing an ultra-thin type semiconductor die according to a fifth embodiment of the present invention will be described in detail.

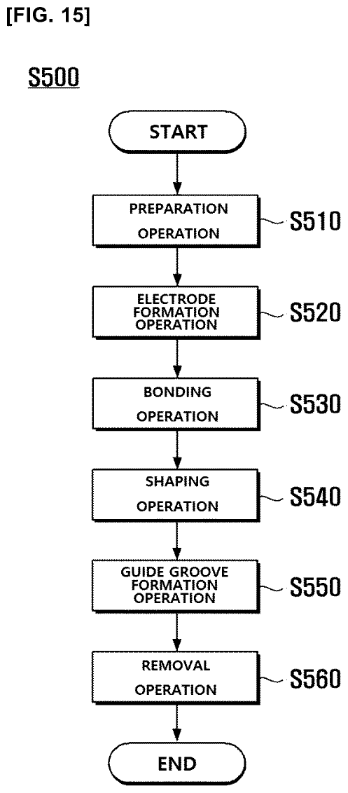

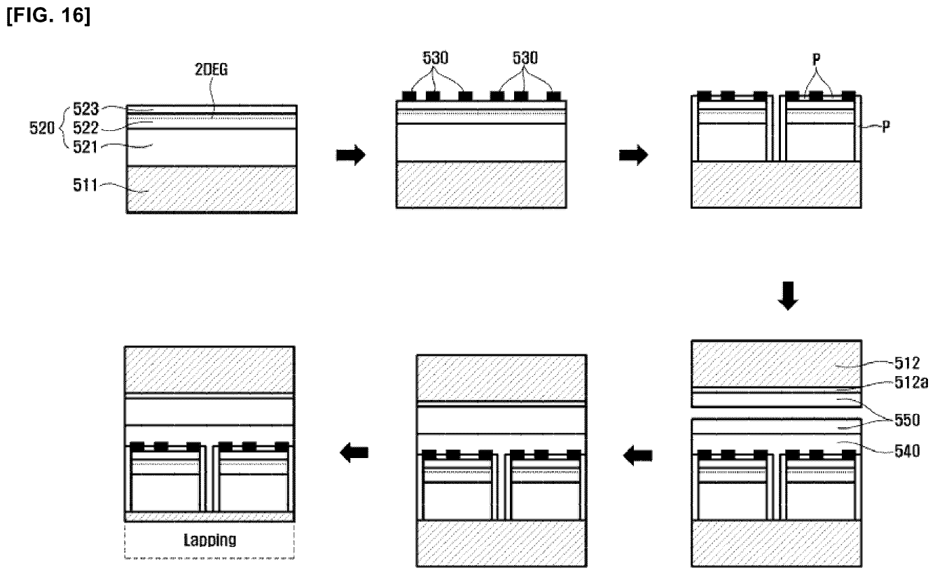

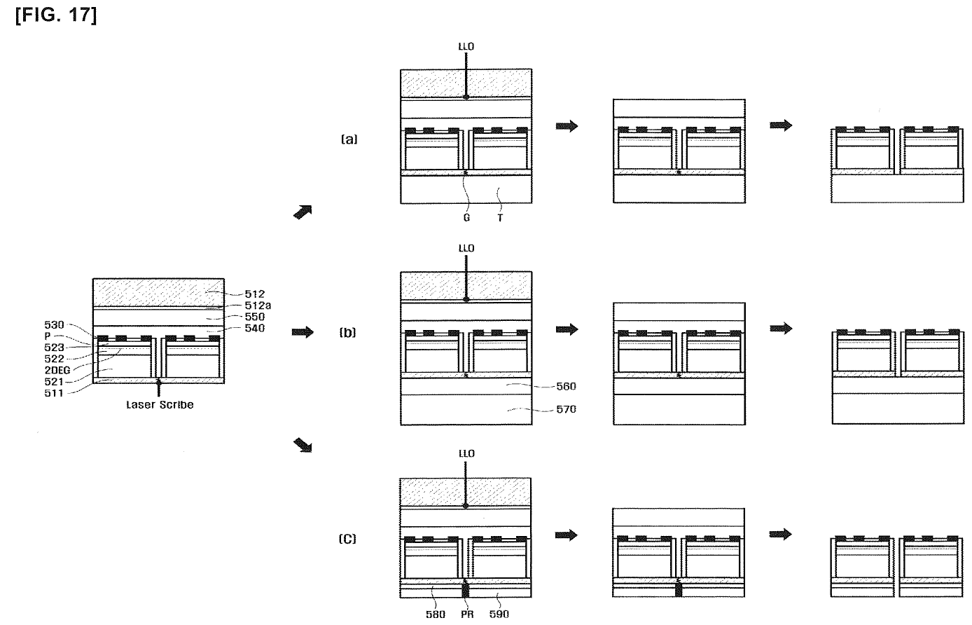

FIG. 15 is a flowchart illustrating the method S500 of manufacturing an ultra-thin type semiconductor die according to the fifth embodiment of the present invention, and FIGS. 16 and 17 are diagrams illustrating a process of manufacturing an ultra-thin type semiconductor die by the method S500 of manufacturing an ultra-thin type semiconductor die according to the fifth embodiment of the present invention.

As shown in FIGS. 15 to 17, the method S500 of manufacturing an ultra-thin type semiconductor die according to the fourth embodiment of the present invention includes a preparation operation S510, an electrode formation operation S520, a bonding operation S530, a shaping operation S540, a guide groove formation operation S550, and a removal operation S560.

The preparation operation S510 is an operation of preparing a first substrate 511 and the second substrate 512 and is an operation of preparing the first substrate 511 on which the semiconductor layer 520 is grown on a top surface.

In the present invention, the first substrate 511 and the second substrate 512 are provided as sapphire substrates. The sapphire substrate is an optically transparent and high-temperature heat-resistant substrate through which 100% of a laser beam (single wavelength light) may pass without absorption (theoretically) in a laser lift-off (LLO) process, which will be described below, and may be provided as α-phase Al₂O₃ sapphire (containing ScAlMgO₄).

Here, the first substrate 511 serves as a growth sapphire substrate and should be positioned so that a surface on which the nitride semiconductor layer 520 of a Group-III nitride, such as GaN, is grown becomes an upper surface, and it is required that both surfaces are polished at a high quality level to be optically transparent.

In addition, the second substrate 512 serves as a carrier sapphire substrate and does not require relatively high quality compared to the first substrate 511, but both surfaces should be polished and optically transparent, and a sacrificial separation layer 512a (sacrificial layer) may be provided on the second substrate 512.

In addition, the separation layer 512a is a layer that is sacrificed and separated when the second substrate 512 is separated using the LLO technique which will be described below. The sacrificial separation layer 512a is formed of a material that enables sacrificial separation by a thermal-chemical decomposition reaction and may be formed of, for example, materials such as ITO, IGZO, ZnO, TiN, InGaN, GaN, InGaON, GaON, SiO₂, SiNₓ, etc., but the present invention is not limited thereto.

Meanwhile, the semiconductor layer 520 may have a structure in which binary, ternary, or quaternary compounds such as GaN, AlGaN, AlN, etc. which are Group-III (Al and Ga) nitride semiconductors, are epitaxially grown in appropriate positions and orders on the first substrate 511.

In addition, in order to minimize crystal defects inside the epitaxial thin film of the Group-III nitride semiconductor layer 520 grown on the top, the first substrate 511 may have a protrusion shape that is regularly or irregularly patterned with various microscale or nanoscale dimensions (sizes and shapes).

More specifically, the semiconductor layer 520 includes a buffer layer 521, a channel layer 522 in which a two-dimensional electron gas (2 DEG) is formed, and a barrier layer 523. The semiconductor layer 520 may have a structure in which the buffer layer 521, the channel layer 522, and the barrier layer 523 are epitaxially grown sequentially on the first substrate 511.

The semiconductor layer 520 is formed of a single layer or multiple layers of Group-III nitride semiconductors and may be formed of GaN, AlGaN, AlN, AlGaN/GaN SLs (superlattice structure), AlN/GaN SLs, AlGaN/AlN SLs, InGaN, InAlN, GaN/InAlN, AlScN, GaN/AlScN, etc., which have high temperature (HT) and high resistance (HR) characteristics. In the semiconductor layer 520, a critical quality factor is to reduce critical crystal defects, i.e., a density of threading dislocations (which are present in a vertical direction relative to an initial growth substrate) (≤low 10⁸/cm²). For example, in the present embodiment, the buffer layer 521 of the semiconductor layer 520 may be formed of GaN or AlN, the channel layer 522 may be formed of GaN, and the barrier layer 523 may be formed of AlGaN.

The electrode formation operation S520 is an operation of forming an electrode 530 on the semiconductor layer 520 by performing a fab process on the semiconductor layer 520.

That is, in the electrode formation operation S520, a fab process of etching the semiconductor layer 520 according to a structure of a power semiconductor device such as a high electron mobility transistor (HEMT), a metal-oxide-silicon field effect transistor (MOSFET), or a junction FET (JFET), as necessary, forming the electrode 530 (at least one of a source electrode, a drain electrode, and a gate electrode) electrically connected to the semiconductor layer 520, and forming a passivation layer P that covers or surrounds at least a portion of the semiconductor layer 520 (preferably covering the entire top and side surfaces of the semiconductor layer 520 so as to prevent the entire top and side surfaces from being exposed) is performed.

In this case, since the semiconductor layer 520 of the present invention is formed for a power semiconductor device, the semiconductor layer 520 is not doped so that it may be difficult for the source electrode and/or the drain electrode to form an ohmic contact. To this end, the ohmic contact may be formed by a method of performing plasma treatment on the semiconductor layer 520, forming the source electrode and/or the drain electrode, and then performing heat treatment at a high temperature of 900 °C or higher.

The bonding operation S530 is an operation of etching and separating the semiconductor layer 520 into die units, forming a protective layer 540 to cover or surround the separated semiconductor layer 520 and the separated electrode 530, and bonding the second substrate 512 to the protective layer 540 through the bonding layer 550.

When a sapphire substrate is bonded to a lower portion of the power semiconductor device, there are advantages in bonding a high-heat dissipation support substrate 570 or forming a Cu electroplated layer 590 for heat dissipation, but there is a disadvantage in terms of heat dissipation due to a thickness of the sapphire substrate itself. To this end, a process technique for a thinner sapphire substrate is also needed in power semiconductor devices.

In this case, when a thickness of the sapphire growth substrate is formed to be thin from the beginning or when the Group-III nitride semiconductor is grown, or when the group III nitride semiconductor is grown, and immediately after, the thickness of the sapphire growth substrate is formed to be thin, a problem occurs in which the die or wafer is deformed and damaged due to thermo-mechanical induced stress generated by a difference in an LC and a CTE between the sapphire growth substrate and the Group-III nitride semiconductor during the shaping process.

Accordingly, according to the present invention, before the first substrate 511, which is a sapphire substrate, is shaped into an ultra-thin shape, the protective layer 540 is formed to cover the semiconductor layer 520 and/or the electrode 530 and then the second substrate 512, which is the same sapphire substrate, is bonded to the protective layer 540 through the bonding layer 550 so that the problem of a wafer being damaged due to thermo-mechanical induced stress generated by a difference in LC and CTE between the thin sapphire growth substrate and the Group-III nitride semiconductor can be solved After the first substrate 511 is shaped into an ultra-thin shape, the thick second substrate 512 is removed to enable the manufacture of a small die (epitaxial die or chip die) having a thickness of less than 100 μm.

Here, the protective layer 540 serves to protect the device structure, and may include, for example, SiO₂, SiNₓ, AlN, Al₂O₃, etc., but the present invention is not limited thereto.

In addition, various bonding methods such as metal bonding, adhesive bonding, and direct bonding may be applied to the bonding layer 550, but the present invention is not limited thereto, and a method that has a strong bonding force and may perform bonding at the lowest possible temperature so as to suppress a bow phenomenon of the epitaxy wafer as much as possible.

The shaping operation S540 is an operation of shaping the first substrate 511 into an ultra-thin shape.

In this case, in order to ensure that the semiconductor die being manufactured is advantageous in terms of heat dissipation, the shaped first sapphire substrate 511 may be shaped to have a thickness of less than 100 μm.

More specifically, the first sapphire substrate 511 is subjected to a lapping process in which mechanical polishing is performed at high speed, and then a mechanical polishing process is performed to allow the first substrate 511 to have an accurate, ultra-thin final thickness. Thereafter, as necessary, as a final shaping operation, the shaping process is completed by performing a CMP process to allow a surface of the first substrate 511 to have surface roughness of 0.5 nm or less. However, the present invention is not limited to the above-described processes and is not limited as long as it is for shaping the first substrate 511 to have the final thickness.

The guide groove formation operation S550 is an operation of forming a guide groove G in the surface of or inside the ultra-thin type shaped first substrate 511 using a laser beam.

Here, the concept of the guide groove G is includes a guide groove, a guide path, a crack, a notch, etc., formed on the surface of or inside the first substrate 511 formed into an ultra-thin shape, and when the second substrate 512 is separated and removed using the LLO technique in a consecutive subsequent process, the guide groove G serves to guide a cut surface when the first substrate 511 is cut (diced) by relieving the residual stress present in the first substrate 511.

More specifically, in order to cut and separate the first substrate 511 into die units in the removal operation S560 which will be described below, a guide groove G may be generated in the surface of or inside each of a plurality of regions of the first substrate 511 in an ultra-thin shape through a process such as laser scribing, laser ablation, or patterning & plasma dry etching in the guide groove formation operation S550.

The removal operation S560 is an operation of removing the second substrate 512 and removing the bonding layer 550 and the protective layer 540.

In this case, as shown in FIG. 17A, in the removal operation S560, a carrier tape T (a tape, such as a blue tape or a UV tape, that is picked and placed) is attached to the first substrate 511 shaped into an ultra-thin shape, the protective layer 540 is dissolved and then the second substrate 512, the bonding layer 550, and the protective layer 540 are removed simultaneously, the second substrate 512 is removed using the LLO technique, and then the remaining sacrificial separation layer 512a, the bonding layer 550, and the protective layer 540 are etched and removed.

Meanwhile, when the guide groove G is formed in the surface of or inside the first substrate 511, which is shaped into the ultra-thin shape, through a laser beam in the shaping operation S540, the thick second substrate 512 is removed in the removal operation S560, the thermo-mechanical induced stress is applied to a corresponding portion in which the guide groove G is formed, and thus cracks propagates to the corresponding portion so that the first substrate 511 may be cut and separated into die units. Meanwhile, after the cutting process, complete separation (or spacing) between dies (or between chips) may be achieved through expansion of the carrier tape T in all directions.

In addition, as shown in FIG. 17B, in the removal operation S560, the high-heat dissipation support substrate 570 may be bonded to the ultra-thin type shaped first substrate 511 through a metal bonding layer 570 so as to improve heat dissipation performance of the power semiconductor device.

Here, the metal bonding layer 570 includes, for example, a metal such as Cu, gold (Au), silver (Ag), palladium (Pd), In, or Sn, or an alloy composed thereof, but the present invention is not limited thereto.

In addition, the high-heat dissipation support substrate 570 may be made of, for example, silicon carbide (SiC), silicon (Si), diamond, AlNcera, or the like, but the present invention is not limited thereto, and a substrate that is suitable for the power semiconductor device to be manufactured may be selected among the substrates. Among the substrates, the AlNcera substrate may be preferentially selected due to advantages such as an increased thickness of a stacked structure, improved composition uniformity, high heat dissipation performance, reduced production costs, and integrated circuit (IC) processability because a CTE matches a stacked structure of the HEMT.

Thereafter, after the second substrate 512, the bonding layer 550, and the protective layer 540 are simultaneously removed by dissolving the protective layer 540, or after the second substrate 512 is removed using the LLO technique, the remaining sacrificial separation layer 512a, the remaining bonding layer 550, and the remaining protective layer 540 are etched and removed.

Meanwhile, when the guide groove G is formed in the surface of or inside the first substrate 511, which is shaped into the ultra-thin shape, through a laser beam in the shaping operation S540, the thick second substrate 512 is removed in the removal operation S560, the thermo-mechanical induced stress is applied to a corresponding portion in which the guide groove G is formed, and thus cracks propagates to the corresponding portion so that the first substrate 511 may be cut and separated into die units.

In addition, as shown in FIG. 17C, in the removal operation S560, a portion PR in which the guide groove G may be formed in the first substrate 511 shaped into an ultra-thin shape is masked at a thickness of about 100 μm using a photoresist or the like, a plating seed layer 580 may be formed on the entire surface of the first substrate 511 excluding the masked portion PR, and then the electroplated layer 590 may be formed on the plating seed layer 580 using an electroplating technique excluding the masked portion PR. In this case, the plating seed layer 580 may be formed of Cr/Cu or Ti/Cu, and the electroplated layer 590 may be formed of Cu. Thereafter, after the second substrate 512, the bonding layer 550, and the protective layer 540 are simultaneously removed by dissolving the protective layer 540, or after the second substrate 512 is removed using the LLO technique, the remaining sacrificial separation layer 512a, the remaining bonding layer 550, and the remaining protective layer 540 are etched and removed and the masked portion PR is also removed.

Meanwhile, when the guide groove G is formed in the surface of or inside the first substrate 511, which is shaped into the ultra-thin shape, through a laser beam in the shaping operation S540, the thick second substrate 512 is removed and the masked portion PR is removed in the removal operation S560, the thermo-mechanical induced stress is applied to a corresponding portion in which the guide groove G is formed, and thus cracks propagates to the corresponding portion so that the first substrate 511 may be cut and separated into die units and the plating seed layer 580 and the electroplated layer 590 may be separated into die units as the masked portion PR is removed.

As described above, although all components constituting the embodiments of the present invention have been described as being combined as one or operating in combination, the present invention is not necessarily limited to these embodiments. That is, within the scope of the present invention, one or more of all the components may be selectively combined and operated.

In addition, the terms “include,” “constitute,” and “have” as described above imply that the corresponding component may be present unless otherwise specifically stated, and therefore they should be construed to further include other components rather than excluding other components. Unless otherwise defined, all terms including technical or scientific terms have the same meaning as commonly understood by those skilled in the art to which the present invention pertains. Commonly used terms, such as terms defined in the dictionary, should be construed as consistent with their contextual meaning in the relevant art and will not be interpreted as having an idealistic or excessively formalistic meaning unless clearly defined in the present specification.

In addition, although embodiments have been described with reference to a number of illustrative embodiments of the technical spirit of the present invention, it should be understood that numerous other modifications and embodiments can be devised by those skilled in the art that will fall within the spirit and scope of the principles of the present invention.

Therefore, embodiments disclosed herein are not to be taken in a sense for limiting the technical spirit of the present invention but for explanation thereof, and the range of the technical spirit of the present invention is not limited to these embodiments. The scope of the present invention should be construed by the appended claims, along with the full range of equivalents to which such claims are entitled.

1. A method of manufacturing an ultra-thin type semiconductor die, the method comprising:
a preparation operation of preparing a first substrate on which a semiconductor layer is grown on a top surface thereof;
a bonding operation of bonding a second substrate to the semiconductor layer through a bonding layer;
a shaping operation of shaping the first substrate into an ultra-thin shape;
a guide groove formation operation of forming a guide groove in a surface of or inside the first substrate, which is shaped into an ultra-thin shape, in a die unit; and
a removal operation of removing the second substrate and the bonding layer.

2. The method of claim 1, wherein, in the removal operation, when the second substrate is removed, cracks are generated from the guide groove of the first substrate, the cracks propagate to the semiconductor layer, and the first substrate and the semiconductor layer are separated into die units due to the propagating cracks.

3. The method of claim 1, wherein the first substrate and the second substrate are sapphire substrates.

4. The method of claim 1, wherein the semiconductor layer includes a first semiconductor region having a first conductivity, a second semiconductor region having a second conductivity different from the first conductivity, and an active region which is interposed between the first semiconductor region and the second semiconductor region and generates light using recombination of electrons and holes.

5. The method of claim 1, further comprising, after the preparation operation, an electrode formation operation of forming an electrode on the semiconductor layer,
wherein the electrode includes at least one of a p-type ohmic electrode and an n-type ohmic electrode.

6-7. (canceled)

8. The method of claim 1, wherein a thickness of the shaped first substrate is less than 50 μm.

9-10. (canceled)

11. A method of manufacturing an ultra-thin type semiconductor die, the method comprising:
a preparation operation of preparing a first substrate on which a semiconductor layer is grown on a top surface thereof;
a bonding operation of bonding a second substrate to the semiconductor layer through a bonding layer;
a shaping operation of removing the first substrate to expose the semiconductor layer, bonding a third substrate to the exposed semiconductor layer through a bonding layer, and then shaping the third substrate into an ultra-thin shape;
a guide groove formation operation of forming a guide groove in a surface of or inside third substrate, which is shaped into an ultra-thin shape, in a die unit; and
a removal operation of removing the second substrate and the bonding layer.

12. The method of claim 11, wherein, in the removal operation, when the second substrate is removed, cracks are generated from the guide groove of the third substrate, the cracks propagate to the semiconductor layer, and the third substrate and the semiconductor layer are separated into die units due to the propagating cracks.

13. The method of claim 11, wherein the first substrate, the second substrate, and the third substrate are sapphire substrates.

14. The method of claim 11, wherein the semiconductor layer includes a first semiconductor region having a first conductivity, a second semiconductor region having a second conductivity different from the first conductivity, and an active region which is interposed between the first semiconductor region and the second semiconductor region and generates light using recombination of electrons and holes.

15. The method of claim 11, further comprising, after the preparation operation, an electrode formation operation of forming an electrode on the semiconductor layer,
wherein the electrode includes at least one of a p-type ohmic electrode and an n-type ohmic electrode.

16-17. (canceled)

18. The method of claim 11, wherein a thickness of the shaped first substrate is less than 50 μm.

19-21. (canceled)

22. A method of manufacturing an ultra-thin type semiconductor die, the method comprising:
a preparation operation of preparing a first substrate on which a semiconductor layer is grown on a top surface thereof;
a bonding operation of etching and separating the semiconductor layer into die units, and then bonding a second substrate to the semiconductor layer through a bonding layer;
a shaping operation of shaping the first substrate into an ultra-thin shape;
a guide groove formation operation of forming a guide groove in a surface of or inside the first substrate, which is shaped into an ultra-thin shape, in a die unit; and
a removal operation of removing the second substrate and the bonding layer.

23. The method of claim 22, wherein, in the removal operation, when the second substrate is removed, cracks are generated from the guide groove of the first substrate, and the first substrate is separated into a die unit due to the generated cracks.

24. The method of claim 22, wherein the first substrate and the second substrate are sapphire substrates.

25. The method of claim 22, wherein the semiconductor layer includes a first semiconductor region having a first conductivity, a second semiconductor region having a second conductivity different from the first conductivity, and an active region which is interposed between the first semiconductor region and the second semiconductor region and generates light using recombination of electrons and holes.

26. The method of claim 25, further comprising, after the preparation operation, an electrode formation operation of forming an electrode on the semiconductor layer,
wherein the electrode includes at least one of a p-type ohmic electrode and an n-type ohmic electrode.

27. (canceled)

28. The method of claim 25, wherein a thickness of the shaped first substrate is less than 50 μm.

29. The method of claim 22, wherein the semiconductor layer includes a buffer layer, a channel layer which is disposed on the buffer layer and in which a two-dimensional electron gas (2 DEG) is formed, and a barrier layer disposed on the channel layer.

30. The method of claim 29, further comprising, after the preparation operation, an electrode formation operation of forming an electrode on the semiconductor layer,
wherein the electrode includes at least one of a source electrode, a drain electrode, and a gate electrode.

31-34.
